(19) United States
(12) Patent Application Publication
(10) Pub. No.: US 2025/0331303 A1
(43) Pub. Date: Oct. 23, 2025

(54) SEMICONDUCTOR DEVICE AND METHOD FOR MANUFACTURING THE SAME

(71) Applicant: SAMSUNG ELECTRONICS CO., LTD., Suwon-si (KR)

(72) Inventors: Jisoo PARK, Suwon-si (KR); Jung Han LEE, Suwon-si (KR); Byung Sung KIM, Suwon-si (KR); Kwan Young CHUN, Suwon-si (KR)

(73) Assignee: SAMSUNG ELECTRONICS CO., LTD., Suwon-si (KR)

(21) Appl. No.: 18/989,946

(22) Filed: Dec. 20, 2024

(30) Foreign Application Priority Data
Apr. 23, 2024 (KR) 10-2024-0054076

(51) Int. Cl. H10D 84/85

(52) U.S. Cl. CPC H10D 84/856; H10D 84/851

(57) ABSTRACT

A semiconductor device includes first and second active patterns extending in a first direction, the second active pattern being spaced apart from the first active pattern in a vertical direction, a first gate structure on the first and second active patterns and extending in a second direction, a first cutting pattern spaced apart from the first and second active patterns in the second direction and cutting the first gate structure, and a via pattern spaced apart from the second active pattern. The second active pattern includes a first portion having a first width, and a second portion having a second width smaller than the first width in the second direction. The first cutting pattern includes first and second line portions, and a first protrusion between the first and second line portions that protrudes from the first line portion. The via pattern extends vertically through the first protrusion.

### CROSS-REFERENCE TO RELATED APPLICATION

This application claims priority from Korean Patent Application No. 10-2024-0054076 filed on Apr. 23, 2024 in the Korean Intellectual Property Office, the contents of which being herein incorporated by reference in its entirety.

### BACKGROUND

The present disclosure relates to a semiconductor device and, more specifically, to a semiconductor device including a stacked multi-gate transistor.

One of scaling schemes for increasing an integration density of an integrated circuit device includes a multi-gate transistor in which a fin-shaped or nanowire-shaped silicon body is formed on a substrate and a gate is formed on a surface of the silicon body.

Because such a multi-gate transistor uses a three-dimensional channel, it is easy to scale the same. Further, current control capability of the multi-gate transistor may be improved without increasing a gate length of the multi-gate transistor. In addition, the multi-gate transistor may effectively suppress short channel effect (SCE) in which a potential of a channel area is affected by drain voltage.

### SUMMARY

It is an aspect to provide a semiconductor device having improved integration density and performance.

According to an aspect of one or more embodiments, there is provided a semiconductor device comprising a first active pattern extending in a first direction; a second active pattern extending in the first direction and being spaced apart from the first active pattern in a vertical direction intersecting the first direction; a first gate structure on the first active pattern and the second active pattern, the first gate structure extending in a second direction intersecting the first direction and the vertical direction; a first cutting pattern spaced apart from the first active pattern and the second active pattern in the second direction, the first cutting pattern extending in the first direction and cutting the first gate structure; and a via pattern spaced apart from the second active pattern in the second direction. The second active pattern includes a first portion having a first width in the second direction; and a second portion having a second width in the second direction that is smaller than the first width. The first cutting pattern includes a first line portion extending in the first direction; and a first protrusion between the first line portion and the second portion, the first protrusion protruding from the first line portion in the second direction, and the via pattern extends in the vertical direction and extends through the first protrusion.

According to another aspect of one or more embodiments, there is provided a semiconductor device comprising a substrate including a first surface and a second surface opposite to the first surface; a first active pattern and a second active pattern sequentially stacked on the first surface along a vertical direction that intersects the first surface, the first active pattern and the second active pattern extending in a first direction and being spaced apart from each other; a gate structure extending in a second direction intersecting the first direction and the vertical direction, the gate structure including a first gate electrode intersecting the first active pattern and a second gate electrode intersecting the second active pattern; a cutting pattern spaced apart from the first active pattern and the second active pattern in the second direction, the cutting pattern extending in the first direction and cutting the gate structure; and a via pattern spaced apart from the second active pattern in the second direction. The second active pattern includes a first portion having a first width in the second direction; and a second portion having a second width in the second direction that is smaller than the first width. The cutting pattern includes a line portion extending in the first direction; and a protrusion between the line portion and the second gate electrode, the protrusion protruding from the line portion in the second direction, and the via pattern extends in the vertical direction to extend through the protrusion, and is connected to the first gate electrode.

According to yet another aspect of one or more embodiments, there is provided a semiconductor device comprising a substrate including a first surface and a second surface opposite to the first surface; a first active pattern and a second active pattern sequentially stacked on the first surface along a vertical direction that intersects the first surface, the first active pattern and the second active pattern extending in a first direction and being spaced apart from each other; a gate structure on the first active pattern and the second active pattern, the gate structure extending in a second direction intersecting the first direction and the vertical direction; a first source/drain contact on a side surface of the gate structure, the first source/drain contact being connected to a first source/drain area of the first active pattern; a second source/drain contact on a side surface of the gate structure, the second source/drain contact being connected to a second source/drain area of the second active pattern; a cutting pattern spaced apart from the first active pattern and the second active pattern in the second direction, the cutting pattern extending in the first direction and cutting the gate structure; and a via pattern spaced apart from the first active pattern and the second active pattern in the second direction. The second active pattern includes a first portion having a first width in the second direction; and a second portion having a second width in the second direction that is smaller than the first width. The cutting pattern includes a line portion extending in the first direction; and a protrusion between the line portion and the second portion, the protrusion protruding from the line portion in the second direction, and the via pattern extends in the vertical direction to extend through the protrusion, and is connected to at least one of the first source/drain contact or the second source/drain contact.

### BRIEF DESCRIPTION OF DRAWINGS

The above and other aspects will become more apparent by describing in detail illustrative embodiments thereof with reference to the attached drawings, in which:

FIG. 1 is an example layout diagram for illustrating semiconductor devices according to some embodiments;

FIG. 2 is a cross-sectional view cut along A-A in FIG. 1, according to some embodiments;

FIG. 3 is a cross-sectional view cut along B-B in FIG. 1, according to some embodiments;

FIG. 4 is a cross-sectional view cut along C-C in FIG. 1, according to some embodiments;

FIG. 5 is a cross-sectional view cut along D-D in FIG. 1, according to some embodiments;

FIG. 6 is a cross-sectional view cut along E-E in FIG. 1, according to some embodiments;

FIG. 7 is another cross-sectional view cut along A-A in FIG. 1, according to some embodiments;

FIG. 8 is another cross-sectional view cut along B-B in FIG. 1, according to some embodiments;

FIG. 9 is another cross-sectional view cut along C-C in FIG. 1, according to some embodiments;

FIG. 10 is an example layout diagram for illustrating a semiconductor device according to some embodiments;

FIG. 11 is an example layout diagram for illustrating semiconductor devices according to some embodiments;

FIG. 12 is a cross-sectional view cut along F-F in FIG. 11, according to some embodiments;

FIG. 13 is an example layout diagram for illustrating a semiconductor device according to some embodiments;

FIG. 14 is a cross-sectional view cut along G-G in FIG. 13, according to some embodiments;

FIG. 15 is a cross-sectional view cut along H-H in FIG. 13, according to some embodiments;

FIG. 16 is a cross-sectional view cut along I-I in FIG. 13, according to some embodiments; and

FIGS. 17 to 19 are various example layout diagrams for illustrating semiconductor devices according to some embodiments.

### DETAILED DESCRIPTIONS

Spatially relative terms, such as “beneath,” “below,” “lower,” “above,” “upper” and the like, may be used herein for ease of description to describe one element or feature's relationship to another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be understood that, although the terms “first”, “second”, etc. may be used herein to describe various elements, these elements should not be limited by these terms. These terms are only used to distinguish one element from another element. Thus, for example, a “first” element, a “first” component or a “first” section discussed below could be termed a “second” element, a “second” component or a “second” section without departing from the teachings of the present disclosure. As used in this specification, the phrase “at least one of A, B, or C” includes within its scope “only A”, “only B”, “only C”, “A and B”, “A and C”, “B and C” and “A, B, and C.”

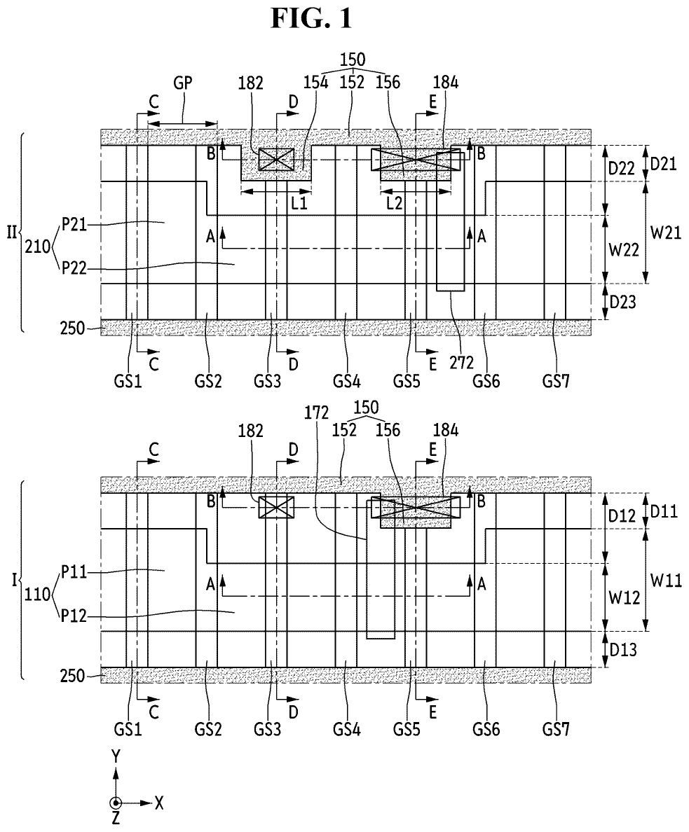

Hereinafter, with reference to FIGS. 1 to 19, a semiconductor device according to some embodiments is described. The embodiments as disclosed in FIGS. 1 to 19 are merely examples, and those skilled in the art will understand that the present disclosure may be applied to various semiconductor devices including various logic elements and/or a static random access memory (SRAM) element.

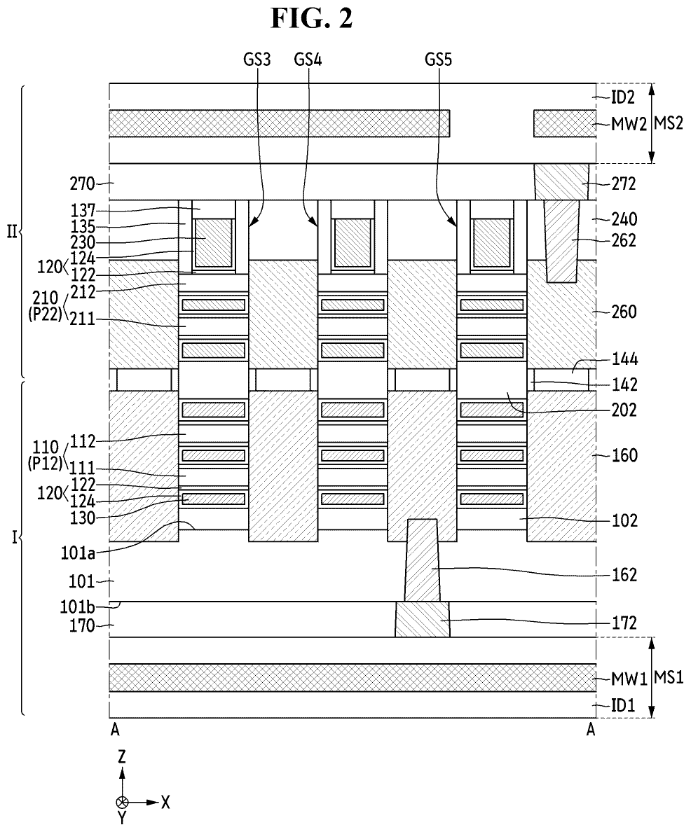

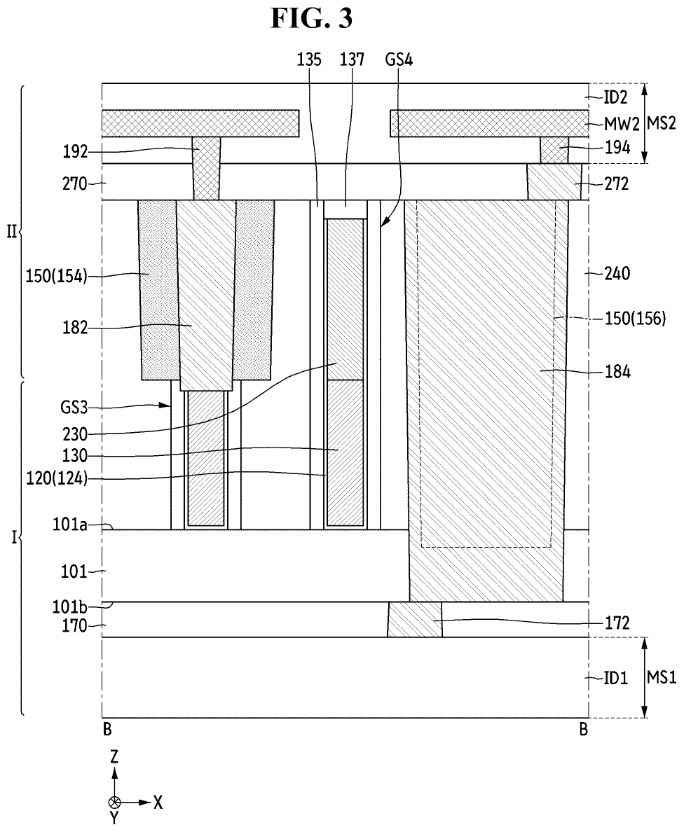

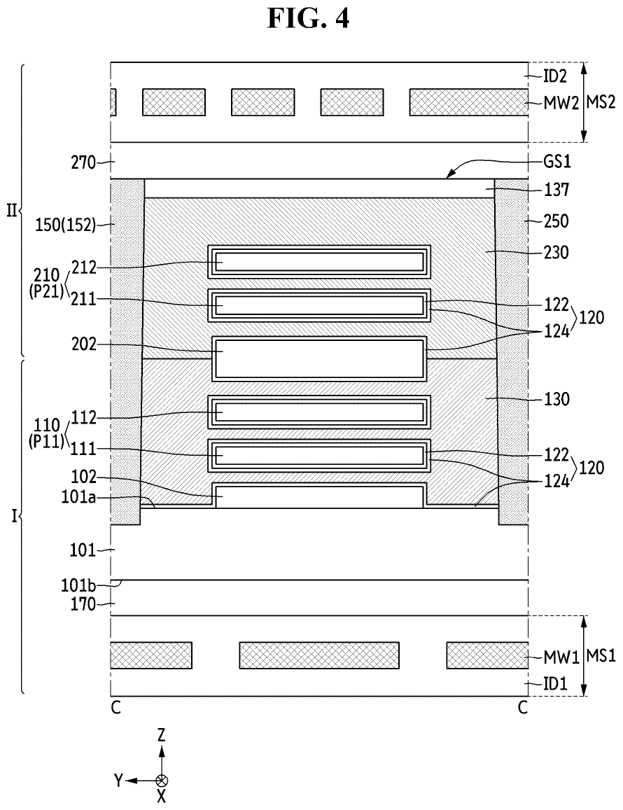

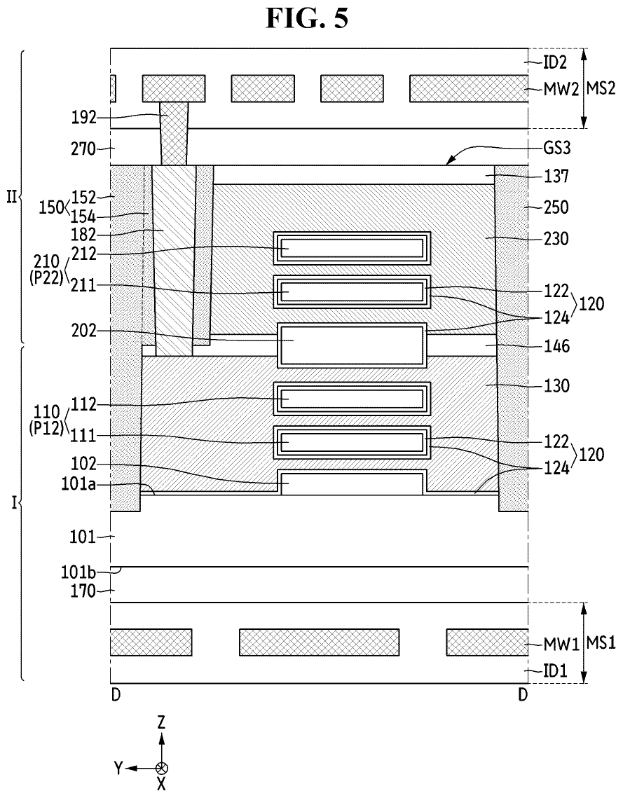

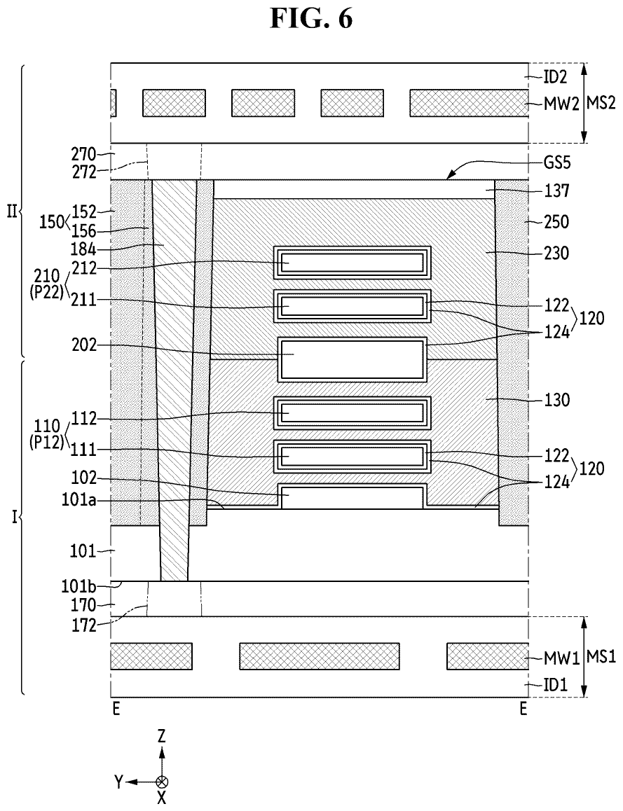

FIG. 1 is an example layout diagram for illustrating semiconductor devices according to some embodiments. FIG. 2 is a cross-sectional view cut along A-A in FIG. 1, according to some embodiments. FIG. 3 is a cross-sectional view cut along B-B in FIG. 1, according to some embodiments. FIG. 4 is a cross-sectional view cut along C-C in FIG. 1, according to some embodiments. FIG. 5 is a cross-sectional view cut along D-D in FIG. 1, according to some embodiments. FIG. 6 is a cross-sectional view cut along E-E in FIG. 1, according to some embodiments.

Referring to FIGS. 1 to 6, the semiconductor device may include a first area I and a second area II.

The first area I and the second area II may be stacked sequentially along a vertical direction Z. In some embodiments, transistors of the same conductivity type may be respectively formed in the first area I and the second area II. In some embodiments, transistors of different conductivity types may be formed may be respectively formed in the first area I and the second area II. In the following description, the first area I is a PFET area and the second area II is a NFET area. However, this is only an example, and a person of ordinary skill in the technical field to which the present disclosure belongs will understand that the first area I may be the NFET area and the second area II may be the PFET area, or both the first area I and the second area II may be NFET areas, or both the first area I and the second area II may be PFET areas.

The semiconductor device may include a substrate 101, a first active pattern 110, a second active pattern 210, first to seventh gate structures GS1 to GS7, a first cutting pattern 150, a second cutting pattern 250, a first source/drain contact 162, a second source/drain contact 262, a first via pattern 182, a second via pattern 184, a first wiring structure MS1, and a second wiring structure MS2.

In some embodiments, the substrate 101 may be made of bulk silicon or silicon-on-insulator (SOI). In some embodiments, the substrate 101 may be a silicon substrate, or may include a material other than silicon, such as silicon germanium, silicon germanium on insulator (SGOI), indium antimonide, lead telluride compound, indium arsenide, indium phosphide, gallium arsenide, or gallium antimonide. In some embodiments, the substrate 101 may have a base substrate and an epitaxial layer formed on the base substrate.

In some embodiments, the substrate 101 may be an insulating substrate including an insulating material. For example, the substrate 101 may include at least one of silicon oxide, silicon oxynitride, silicon oxycarbonitride, or combinations thereof. However, embodiments of the present disclosure are not limited thereto. For example, in some embodiments, the substrate 101 may include a silicon oxide film.

The substrate 101 may include a first surface 101a and a second surface 101b, which are opposite to each other. In the present disclosure, the first surface 101a may be referred to as a front surface of the substrate 101, and the second surface 101b may be referred to as a back surface of the substrate 101.

The first active pattern 110 and the second active pattern 210 may be sequentially stacked on the first surface 101a of the substrate 101. The first active pattern 110 and the second active pattern 210 may be spaced apart from each other in the vertical direction Z. The first active pattern 110 may be disposed within the first area I, and the second active pattern 210 may be disposed within the second area II. Each of the first active pattern 110 and the second active pattern 210 may extend in an elongate manner in a first direction X intersecting the vertical direction Z.

In some embodiments, the first active pattern 110 may include a plurality of lower bridge patterns 111 and 112 that are sequentially stacked on the substrate 101 and spaced apart from each other. In some embodiments, the second active pattern 210 may include a plurality of upper bridge patterns 211 and 212 that are sequentially stacked on the first active pattern 110 and are spaced apart from each other. Each of the first active pattern 110 and the second active pattern 210 may be used as a channel area of a MBCFET® including a multi-bridge channel. While FIG. 2 shows two bridge patterns in each of the first active pattern 110 and the second active pattern 210, the number of bridge patterns included in each of the first active pattern 110 and the second active pattern 210 is merely an example and is not limited to what is shown.

In some embodiments, each of the first active pattern 110 and the second active pattern 210 may include silicon Si or germanium Ge as an elemental semiconductor material. In some embodiments, each of the first active pattern 110 and the second active pattern 210 may include a compound semiconductor, for example, a group IV-IV compound semiconductor or a group III-V compound semiconductor. The group IV-IV compound semiconductor may include, for example, a binary compound including two of carbon (C), silicon (Si), germanium (Ge), and tin (Sn), a ternary compound including three thereof, or a compound obtained by doping a group IV element thereto. The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminum (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other.

In some embodiments, the first active pattern 110 may include a first portion P11 and a second portion P12 having different widths. For example, the first portion P11 may have a first width W11 in a second direction Y, and the second portion P12 may have a second width W12 in the second direction Y that is smaller than the first width W11. The first portion P11 and the second portion P12 may be connected to each other in the first direction X.

In some embodiments, the second active pattern 210 may include a third portion P21 and a fourth portion P22 having different widths. For example, the third portion P21 may have a third width W21 in the second direction Y, and the fourth portion P22 may have a fourth width W22 in the second direction Y that is smaller than the third width W21. The third portion P21 and the fourth portion P22 may be connected to each other in the first direction X.

In some embodiments, the first portion P11 of the first active pattern 110 and the third portion P21 of the second active pattern 210 may overlap each other in the vertical direction Z. In some embodiments, the second portion P12 of the first active pattern 110 and the fourth portion P22 of the second active pattern 210 may overlap each other in the vertical direction Z.

In some embodiments, a base insulating pattern 102 may be formed between the substrate 101 and the first active pattern 110. The base insulating pattern 102 may extend in an elongate manner in the first direction X. The base insulating pattern 102 may electrically insulate the substrate 101 and the first active pattern 110 from each other. The base insulating pattern 102 may include, but is not limited to, at least one of, for example, silicon oxide, silicon oxynitride, silicon oxycarbonitride, or combinations thereof. For example, in some embodiments, the base insulating pattern 102 may include a silicon nitride film.

In some embodiments, an intermediate insulating pattern 202 may be formed between the first active pattern 110 and the second active pattern 210. The intermediate insulating pattern 202 may extend in an elongate manner in the first direction X. The intermediate insulating pattern 202 may electrically insulate the first active pattern 110 and the second active pattern 210 from each other. The intermediate insulating pattern 202 may include, but is not limited to, at least one of silicon oxide, silicon oxynitride, silicon oxycarbonitride, or combinations thereof. For example, in some embodiments, the intermediate insulating pattern 202 may include a silicon nitride film.

Each of the first to seventh gate structures GS1 to GS7 may be disposed on the first active pattern 110 and the second active pattern 210. Each of the first to seventh gate structures GS1 to GS7 may intersect the first active pattern 110 and the second active pattern 210. For example, each of the first to seventh gate structures GS1 to GS7 may extend in an elongate manner in the second direction Y that intersects the vertical direction Z and the first direction X. The first to seventh gate structures GS1 to GS7 may be spaced apart from each other in the first direction X.

In the present disclosure, adjacent gate structures may be referred to as being spaced apart from each other by 1 gate pitch (1 GP). The 1 gate pitch (1 GP) may be defined as a sum of a distance between two adjacent gate structures and a width of one gate structure. Similarly, the 1 gate pitch (1 GP) may be defined as a distance between a center line of one gate structure and a center line of another gate structure adjacent thereto.

The first to seventh gate structures GS1 to GS7 may intersect the first portion P11 of the first active pattern 110 and/or the second portion P12 of the first active pattern 110. For example, each of the first and seventh gate structures GS1 and GS7 may intersect the first portion P11 of the first active pattern 110. For example, each of the third to fifth gate structures GS3 to GS5 may intersect the second portion P12 of the first active pattern 110. For example, each of the second and sixth gate structures GS2 and GS6 may intersect a boundary area between the first portion P11 and the second portion P12.

The first to seventh gate structures GS1 to GS7 may intersect with the third portion P21 of the second active pattern 210 and/or the fourth portion P22 of the second active pattern 210. For example, each of the first and seventh gate structures GS1 and GS7 may intersect with the third portion P21 of the second active pattern 210. For example, each of the third to fifth gate structures GS3 to GS5 may intersect the fourth portion P22 of the second active pattern 210. For example, each of the second and sixth gate structures GS2 and GS6 may intersect a boundary area between the third portion P21 and the fourth portion P22.

In some embodiments, each of the first to seventh gate structures GS1 to GS7 may surround the first active pattern 110 and the second active pattern 210. For example, each of bridge patterns 111, 112, 211, and 212 may extend in the first direction X so as to extend through the first to seventh gate structures GS1 to GS7.

Each of the first to seventh gate structures GS1 to GS7 may include a gate dielectric film 120, a first gate electrode 130, a second gate electrode 230, a gate spacer 135, and a gate capping film 137.

The gate dielectric film 120 may be interposed between the first active pattern 110 and the first gate electrode 130 and between the second active pattern 210 and the second gate electrode 230. The gate dielectric film 120 may include at least one of a dielectric material, for example, silicon oxide, silicon oxynitride, silicon nitride, or a high dielectric constant material having a higher dielectric constant than the dielectric constant of silicon oxide. The high dielectric constant material may include at least one of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate or combinations thereof. However, embodiments of the present disclosure are not limited thereto.

In some embodiments, the gate dielectric film 120 may include an interfacial film 122 and a high dielectric layer 124 that are sequentially stacked on the first active pattern 110 and the second active pattern 210.

The interfacial film 122 may surround each of the bridge patterns 111, 112, 211, and 212. For example, the interfacial film 122 may extend conformally along a periphery of each of the bridge patterns 111, 112, 211, and 212. In some embodiments, the interfacial film 122 may include an oxide film produced by oxidizing a surface of each of the bridge patterns 111, 112, 211, and 212. For example, when each of the bridge patterns 111, 112, 211, and 212 includes silicon (Si), the interfacial film 122 may include a silicon oxide film.

The high-k dielectric film 124 may surround a periphery of the interfacial film 122. Moreover, a portion of the high-k dielectric layer 124 may be interposed between the second gate electrode 230 and the gate spacer 135. For example, the high-k dielectric film 124 may extend conformally along the periphery of the interfacial film 122 and a profile of an inner side surface of the gate spacer 135. The high-k dielectric layer 124 may further extend along the substrate 101, the base insulating pattern 102, and the intermediate insulating pattern 202.

In some embodiments, the high-k dielectric layer 124 may include a high-k material with a dielectric constant greater than the dielectric constant of silicon oxide. The high dielectric constant material may include at least one of for example, hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}) or combinations thereof. However, embodiments of the present disclosure are not limited thereto.

The first gate electrode 130 may be disposed within the first area I. The first gate electrode 130 may intersect the first active pattern 110. For example, the first active pattern 110 may extend in the first direction X and extend through the first gate electrode 130.

The second gate electrode 230 may be disposed within the second area II. The second gate electrode 230 may intersect the second active pattern 210. For example, the second active pattern 210 may extend in the first direction X and extend through the second gate electrode 230.

Each of the first gate electrode 130 and the second gate electrode 230 may include a conductive material, for example, at least one of TiN, WN, TaN, Ru, TiC, TaC, Ti, Ag, Al, TiAl, TiAlN, TiAlC, TaCN, TaSiN, Mn, Zr, W, Al, or combinations thereof. However, embodiments of the present disclosure are not limited thereto. Each of the first gate electrode 130 and the second gate electrode 230 may be formed in a replacement process. However, embodiments of the present disclosure are not limited thereto.

Each of the first gate electrode 130 and the second gate electrode 230 is shown as a single film. However, this is only an example. In some embodiments, each of the first gate electrode 130 and the second gate electrode 230 may be formed by stacking a plurality of conductive films. For example, each of the first gate electrode 130 and the second gate electrode 230 may include a work function control film that controls a work function, and a filling conductive film that fills a space defined by the work function control film. For example, the work function control film may include at least one of TiN, TaN, TiC, TaC, TiAlC, or combinations thereof. The filling conductive film may include, for example, W or Al.

In some embodiments, the first gate electrode 130 and the second gate electrode 230 may include different conductive materials. For example, the first gate electrode 130 and the second gate electrode 230 may include work function control films of different conductivity types, respectively. For example, the first gate electrode 130 may include a p-type work function control film, and the second gate electrode 230 may include an n-type work function control film.

In some embodiments, the first gate electrode 130 and the second gate electrode 230 of some of the first to seventh gate structures GS1 to GS7 may be electrically connected to each other. For example, as shown in FIG. 4, the first gate electrode 130 and the second gate electrode 230 of the first gate structure GS1 may contact each other. In an example, as shown in FIG. 6, the first gate electrode 130 and the second gate electrode 230 of the fifth gate structure GS5 may contact each other.

In some embodiments, the first gate electrode 130 and the second gate electrode 230 of the others of the first to seventh gate structures GS1 to GS7 may be electrically insulated from each other. For example, as shown in FIG. 5, the third gate structure GS3 may include a gate insulating pattern 146 between the first gate electrode 130 and the second gate electrode 230 thereof. The gate insulating pattern 146 may extend in an elongate manner in the second direction Y. The first gate electrode 130 and the second gate electrode 230 of the third gate structure GS3 may be insulated from each other via the gate insulating pattern 146.

The gate spacer 135 may extend along a side surface of the first gate electrode 130 and a side surface of the second gate electrode 230. Each of the first active pattern 110 and the second active pattern 210 may extend in the first direction X and extend through the gate spacer 135. The gate spacer 135 may include an insulating material including at least one of silicon oxide, silicon nitride, silicon oxynitride, silicon oxycarbide, silicon boron nitride, silicon boron carbonitride, silicon oxycarbonitride, or combinations thereof. However, embodiments of the present disclosure are not limited thereto.

The gate capping film 137 may extend along an upper surface of the second gate electrode 230. The gate capping film 137 may include an insulating material including at least one of silicon oxide, silicon nitride, silicon oxynitride, silicon oxycarbide, silicon boron nitride, silicon boron carbonitride, silicon oxycarbonitride, or combinations thereof. However, embodiments of the present disclosure are not limited thereto.

The first active pattern 110 may include the first source/drain areas 160. The first source/drain area 160 may be formed in the first active pattern 110 on a side surface of the first to seventh gate structures GS1 to GS7. The lower bridge patterns 111 and 112 may extend through the first gate electrode 130 and the gate spacer 135 so as to contact the first source/drain area 160. The first source/drain area 160 may be insulated from the first gate electrode 130 via the gate spacer 135 and/or the gate dielectric film 120.

In some embodiments, the first source/drain area 160 may include an epitaxial layer doped with impurities. For example, the first source/drain area 160 may include an epitaxial pattern grown from the first active pattern 110 in an epitaxial growth method. When the first active pattern 110 is a channel area of a PFET, the first source/drain area 160 may contain P-type impurities (e.g., B, In, Ga or Al) or impurities for preventing diffusion of the P-type impurities.

The second active pattern 210 may include the second source/drain areas 260. The second source/drain area 260 may be formed in the second active pattern 210 on a side surface of each of the first to seventh gate structures GS1 to GS7. The upper bridge patterns 211 and 212 may extend through the second gate electrode 230 and the gate spacer 135 so as to contact the second source/drain area 260. The second source/drain area 260 may be insulated from the second gate electrode 230 via the gate spacer 135 and/or the gate dielectric film 120.

In some embodiments, the second source/drain area 260 may include an epitaxial layer doped with impurities. For example, the second source/drain area 260 may include an epitaxial pattern grown from the second active pattern 210 in an epitaxial growth method. When the second active pattern 210 is a channel area of an NFET, the second source/drain area 260 may contain N-type impurities (e.g., P, Sb, or As) or impurities to prevent diffusion of the N-type impurities.

In some embodiments, an intermediate insulating layer 144 may be formed between the first source/drain area 160 and the second source/drain area 260. The intermediate insulating layer 144 may cover the first source/drain area 160, and the second source/drain area 260 may be formed on the intermediate insulating layer 144. The intermediate insulating layer 144 may electrically insulate the first source/drain area 160 and the second source/drain area 260 from each other. The intermediate insulating layer 144 may include, but is not limited to, at least one of silicon oxide, silicon oxynitride, silicon oxycarbonitride, or combinations thereof.

In some embodiments, an intermediate spacer 142 may be formed between the intermediate insulating pattern 202 and the intermediate insulating layer 144. The intermediate spacer 142 may extend along a side surface of the intermediate insulating pattern 202. The intermediate spacer 142 may be interposed between the first source/drain area 160 and the second source/drain area 260. The intermediate spacer 142 may include, but is not limited to, an insulating material, for example, at least one of silicon oxide, silicon oxynitride, silicon oxycarbonitride, or combinations thereof.

A first interlayer insulating film 240 may fill a space on an outer side surface of the gate spacer 135. The first interlayer insulating film 240 may include at least one of, for example, silicon oxide, silicon nitride, silicon oxynitride, silicon oxycarbide, silicon boron nitride, boron silicon carbonitride, silicon oxycarbonitride, or a low dielectric constant material with a smaller dielectric constant than the dielectric constant of silicon oxide. However, embodiments of the present disclosure are not limited thereto.

A first cutting pattern 150 and a second cutting pattern 250 may be spaced apart from each other in the second direction Y. The first active pattern 110 and the second active pattern 210 may be interposed between the first cutting pattern 150 and the second cutting pattern 250. The first cutting pattern 150 may be spaced apart from one side of the first active pattern 110 and one side of the second active pattern 210 in the second direction Y. The second cutting pattern 250 may be spaced apart from the other side of the first active pattern 110 and the other side of the second active pattern 210 in the second direction Y.

Each of the first cutting pattern 150 and the second cutting pattern 250 may extend in an elongate manner in the first direction X and may cut the first to seventh gate structures GS1 to GS7. Each of the first cutting pattern 150 and the second cutting pattern 250 may include an insulating material, such as at least one of silicon oxide, silicon nitride, silicon oxynitride, silicon oxycarbide, silicon boron nitride, silicon boron carbonitride, or silicon oxycarbonitride, or combinations thereof. However, embodiments of the present disclosure are not limited thereto.

It is shown that the uppermost surface of the first cutting pattern 150 and the uppermost surface of the second cutting pattern 250 are coplanar on an upper surface of the gate capping film 137 (see, e.g., FIG. 5). However, this is only an example. As long as the first cutting pattern 150 and the second cutting pattern 250 only cut the first gate electrode 130 and the second gate electrode 230, a vertical level of each of the uppermost surface of the first cutting pattern 150 and the uppermost surface of the pattern 250 may be higher or lower than a vertical level of the upper surface of the gate capping film 137.

It is shown that a vertical level of each of the lowermost surface of the first cutting pattern 150 and the lowermost surface of the second cutting pattern 250 is lower than a vertical level of the uppermost surface of the substrate 101. However, this is only an example. As long as the first cutting pattern 150 and the second cutting pattern 250 only cut the first gate electrode 130 and the second gate electrode 230, the lowermost surface of the first cutting pattern 150 and the lowermost surface of the second cutting pattern 250 may be coplanar with the uppermost surface of the substrate 101.

In some embodiments, the first cutting pattern 150 may include a first line portion 152, a first protrusion 154, and a second protrusion 156.

The first line portion 152 may extend in the first direction X to cut the first to seventh gate structures GS1 to GS7. A first distance D11 in the second direction Y between the first portion P11 of the first active pattern 110 and the first line portion 152 may be smaller than a second distance D12 in the second direction Y between the second portion P12 of the first active pattern 110 and the first line portion 152. A third distance D21 in the second direction Y between the third portion P21 of the second active pattern 210 and the first line portion 152 may be smaller than a fourth distance D22 in the second direction Y between the fourth portion P22 of the second active pattern 210 and the first line portion 152.

In some embodiments, a fifth distance D13 in the second direction Y between the first active pattern 110 and the second cutting pattern 250 may be smaller than the second distance D12. For example, in some embodiments, the fifth distance D13 may be the equal to the first distance D11. In some embodiments, a sixth distance D23 in the second direction Y between the second active pattern 210 and the second cutting pattern 250 may be smaller than the fourth distance D22. For example, in some embodiments, the sixth distance D23 may be equal to the third distance D21. In the present disclosure, “being equal to” means not only “being exactly equal to” but also including a minor difference that may occur due to a process margin, etc. In some embodiments, each of a distance in the second direction Y between the first portion P11 of the first active pattern 110 and the second cutting pattern 250 and a distance in the second direction Y between the second portion P12 of the first active pattern 110 and the second cutting pattern 250 may be equal to the fifth distance D13. In some embodiments, each of a distance in the second direction Y between the third portion P21 of the second active pattern 210 and the second cutting pattern 250 and a distance in the second direction Y between the fourth portion P22 of the second active pattern 210 and the second cutting pattern 250 may be equal to the sixth distance D23.

The first protrusion 154 may protrude from the first line portion 152 in the second direction Y, as illustrated in FIG. 1. The first protrusion 154 may be interposed between the first line portion 152 and the fourth portion P22 of the second active pattern 210. A distance in the second direction Y between the first protrusion 154 and the fourth portion P22 is shown to be equal to the third distance D21. However, this is only an example.

The first protrusion 154 may additionally cut the second gate electrode 230 of the third gate structure GS3. For example, the first protrusion 154 may be interposed between the second gate electrode 230 and the first line portion 152 of the third gate structure GS3. A length by which the second gate electrode 230 of the third gate structure GS3 extends in the second direction Y may be smaller than a length by which another second gate electrode (e.g., the second gate electrode 230 of each of the second and fourth gate structures GS2 and GS4) that is not cut by the first protrusion 154 extends. In FIG. 5, a vertical level of the lowermost surface of the first protrusion 154 is shown to be higher than a vertical level of the lowermost surface of the gate insulating pattern 146. However, this is only an example. As long as the first protrusion 154 cuts the second gate electrode 230, the vertical level of the lowermost surface of the first protrusion 154 may be equal to or lower than the vertical level of the lowermost surface of the gate insulating pattern 146.

In some embodiments, the first protrusion 154 may not cut the first gate electrode 130 of the third gate structure GS3. For example, the first protrusion 154 may not be interposed between the first gate electrode 130 of the third gate structure GS3 and the first line portion 152. A length by which the first gate electrode 130 of the third gate structure GS3 extends in the second direction Y may be larger than a length by which the second gate electrode 230 of the third gate structure GS3 extends in the second direction Y.

In some embodiments, the first protrusion 154 may be interposed between the second gate structure GS2 and the fourth gate structure GS4. For example, a first length L1 by which the first protrusion 154 extends in the first direction X may be about 1 gate pitch (1 GP).

The second protrusion 156 may protrude from the first line portion 152 in the second direction Y. The second protrusion 156 may be interposed between the first line portion 152 and the fourth portion P22 of the second active pattern 210. A distance in the second direction Y between the second protrusion 156 and the fourth portion P22 is shown to be equal to the third distance D21. However, this is only an example. The second protrusion 156 may be spaced apart from the first protrusion 154 in the first direction X.

The second protrusion 156 may additionally cut the fifth gate structure GS5. For example, the second protrusion 156 may be interposed between the fifth gate structure GS5 and the first line portion 152. A length by which the fifth gate structure GS5 extends in the second direction Y may be smaller than a length by which another gate structure (e.g., each of fourth and sixth gate structures GS4 and GS6) that is not cut by the second protrusion 156 extends.

In some embodiments, the second protrusion 156 may cut both the first gate electrode 130 and the second gate electrode 230 of the fifth gate structure GS5. For example, the second protrusion 156 may be disposed between the first gate electrode 130 of the fifth gate structure GS5 and the first line portion 152 and the second gate electrode 230 of the fifth gate structure GS5 and the second line portion 252. In FIG. 6, a vertical level of the lowermost surface of the second protrusion 156 is shown to be lower than a vertical level of the uppermost surface of the substrate 101. However, this is only an example. As long as the second protrusion 156 cuts the fifth gate structure GS5, the lowermost surface of the second protrusion 156 may be coplanar with the uppermost surface of the substrate 101.

In some embodiments, the second protrusion 156 may be interposed between the fourth gate structure GS4 and the sixth gate structure GS6. For example, a second length L2 by which the second protrusion 156 extends in the first direction X may be approximately 1 gate pitch (1 GP). In some embodiments, L2 may be equal to L1.

The first source/drain contact 162 may be electrically connected to the first active pattern 110. For example, the first source/drain contact 162 may extend in the vertical direction Z through the substrate 101 so as to contact the first source/drain area 160.

The second source/drain contact 262 may be electrically connected to the second active pattern 210. For example, the second source/drain contact 262 may extend in the vertical direction Z through the first interlayer insulating film 240 so as to contact the second source/drain area 260.

The first via pattern 182 may be spaced apart from the fourth portion P22 of the second active pattern 210 in the second direction Y. The first via pattern 182 may extend in the vertical direction Z through the first protrusion 154. In some embodiments, the first via pattern 182 may extend through the first protrusion 154 and the gate insulating pattern 146. The first via pattern 182 may include a conductive material, for example, tungsten (W) or aluminum (Al). However, embodiments of the present disclosure are not limited thereto.

In some embodiments, the first via pattern 182 may contact the first gate electrode 130 of the third gate structure GS3. For example, the first via pattern 182 may extend through the first protrusion 154 and/or the gate insulating pattern 146 of the third gate structure GS3 so as to contact an upper surface of the first gate electrode 130 of the third gate structure GS3. The first via pattern 182 may be spaced apart from the second gate electrode 230 of the third gate structure GS3 via the first protrusion 154. That is, the first via pattern 182 may be electrically connected to the first gate electrode 130 of the third gate structure GS3, and may not be electrically connected to the second gate electrode 230 of the third gate structure GS3.

The second via pattern 184 may be spaced apart from the fourth portion P22 of the second active pattern 210 in the second direction Y. The second via pattern 184 may extend in the vertical direction Z through the second protrusion 156. In some embodiments, the second via pattern 184 may extend through the second protrusion 156 and the substrate 101. The second via pattern 184 may include a conductive material, for example, W or Al. However, embodiments of the present disclosure are not limited thereto.

In some embodiments, the second via pattern 184 may contact at least one of the first active pattern 110 or the second active pattern 210.

For example, the second interlayer insulating film 170 and a first connection contact 172 disposed within the second interlayer insulating film 170 may be formed on the second surface 101b of the substrate 101. The first connection contact 172 may extend in the second direction Y. Each of the first source/drain contact 162 and the second via pattern 184 may be connected to the first connection contact 172 in the vertical direction Z. That is, the second via pattern 184 may be connected to the first source/drain area 160 via the first connection contact 172 and the first source/drain contact 162. In some embodiments, the first connection contact 172 may be omitted. For example, unlike what is shown, the first source/drain contact 162 may extend in the second direction Y so as to directly contact the second via pattern 184.

In some embodiments, for example, a third interlayer insulating film 270 and a second connection contact 272 disposed within the third interlayer insulating film 270 may be formed on the first interlayer insulating film 240. The second connection contact 272 may extend in the second direction Y. Each of the second source/drain contact 262 and the second via pattern 184 may be connected to the second connection contact 272 in the vertical direction Z. That is, the second via pattern 184 may be connected to the second source/drain area 260 via the second connection contact 272 and the second source/drain contact 262. In some embodiments, the second connection contact 272 may be omitted. For example, unlike what is shown, the second source/drain contact 262 may extend in the second direction Y so as to directly contact the second via pattern 184.

In some embodiments, the second via pattern 184 may connect the first source/drain area 160 and the second source/drain area 260 to each other. For example, as shown, the first connection contact 172 may be disposed on one side of the fifth gate structure GS5, and the second connection contact 272 may be disposed on the other side of the fifth gate structure GS5. The second via pattern 184 may extend in the first direction X so as to connect the first connection contact 172 and the second connection contact 272 to each other.

The first wiring structure MS1 may be formed on the second surface 101b of the substrate 101. For example, the first wiring structure MS1 may include a first inter-wiring insulating film ID1 covering the second interlayer insulating film 170 and a plurality of first wiring patterns MW1 disposed within the first inter-wiring insulating film ID1. The first wiring patterns MW1 may be insulated from each other via the first inter-wiring insulating film ID1.

In some embodiments, at least some of the first wiring patterns MW1 may act as a power line (e.g., V_{SS} or V_{DD}) that supplies power to the first area I and/or the second area II.

The second wiring structure MS2 may be formed on the first surface 101a of the substrate 101. For example, the second wiring structure MS2 may include a second inter-wiring insulating film ID2 covering the third interlayer insulating film 270 and a plurality of second wiring patterns MW2 disposed in the second inter-wiring insulating film ID2. The second wiring patterns MW2 may be insulated from each other via the second inter-wiring insulating film ID2.

In some embodiments, at least some of the second wiring patterns MW2 may be electrically connected to the first wiring patterns MW1 acting as the power line.

In some embodiments, the first via pattern 182 and/or the second via pattern 184 may be electrically connected to the second wiring structure MS2. For example, a first front via 192 may be formed so as to connect some of the second wiring patterns MW2 and the first via pattern 182 to each other. In some embodiments, for example, a second front via 194 may be formed so as to connect some of the second wiring patterns MW2 and the second connection contact 272 to each other. The second via pattern 184 may be connected to the first wiring structure MS1 via the second connection contact 272 and the second front via 194.

As the semiconductor device becomes more highly integrated, individual circuit patterns are becoming increasingly smaller to implement a larger number of elements in the same area. For this purpose, the semiconductor device using a stacked multi-gate transistor in which a multi-gate transistor in an upper area (e.g., the second area II) is stacked on top of a multi-gate transistor in a lower area (e.g., the first area I) is being researched. However, in this semiconductor device, it may be difficult to improve the integration density due to the complexity of the circuit patterns.

For example, in order to connect the lower and upper areas to each other, a tall via that extends in an elongate manner across the lower and upper areas may be required. However, in using the tall via, an area size adjacent to the gate structure of the tall via is larger than an area size adjacent to the gate structure of a via extending only in the lower area or a via extending only in the upper area. This structure may increase the parasitic capacitance between the tall via and the gate structure to reduce the performance of the semiconductor device. Moreover, the tall via may be disposed outside an area where the active pattern and the gate structure are disposed in a plan view (that is, the tall via does not overlap the active pattern and the gate structure in the vertical direction Z). This structure may increase an area size required to implement the semiconductor device, thereby limiting improvement of the integration density.

However, in the semiconductor device according to some embodiments, the first area I and the second area II may be connected to each other using the first via pattern 182 and/or the second via pattern 184 such that improved integration density and performance may be achieved.

For example, as described above, the first cutting pattern 150 may include the first protrusion 154 protruding toward the fourth portion P22 of the second active pattern 210. The first via pattern 182 may extend through the first protrusion 154 so as to connect the first area I (e.g., the first gate electrode 130) and the second area II (e.g., the second wiring structure MS2) to each other. In this regard, the third portion P21 of the second active pattern 210 does not overlap the first protrusion 154 thereof in the second direction Y so that the third portion P21 may have a relatively larger width. For example, the third width W21 of the third portion P21 may be larger than the fourth width W22 of the fourth portion P22. Thus, the semiconductor device with improved integration density and performance may be provided.

In some embodiments, for example, as described above, the first cutting pattern 150 may include the second protrusion 156 which protrudes toward the second portion P12 of the first active pattern 110 and the fourth portion P22 of the second active pattern 210. The second via pattern 184 may extend through the second protrusion 156 so as to connect the first area I (e.g., the first source/drain area 160) and the second area II (e.g., the second source/drain area 260) to each other. In this regard, the first portion P11 of the first active pattern 110 and the third portion P21 of the second active pattern 210 do not overlap the second protrusion 156 in the second direction Y, such that each of the first portion P11 of the first active pattern 110 and the third portion P21 of the second active pattern 210 may have a relatively larger width. For example, each of the first width W11 of the first portion P11 and the third width W21 of the third portion P21 may be larger than each of the second width W12 of the second portion P12 and the fourth width W22 of the fourth portion P22. Thus, a semiconductor device with improved integration density and performance may be provided.

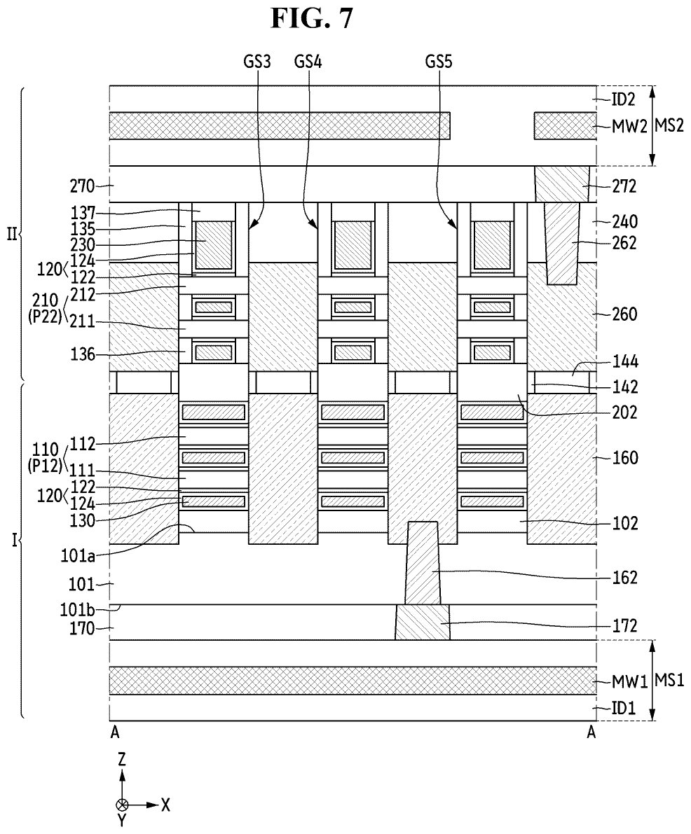

FIG. 7 is another cross-sectional view cut along A-A in FIG. 1, according to some embodiments. For convenience of description, components duplicated with those as described above using FIGS. 1 to 6 are briefly described or descriptions thereof are omitted for conciseness.

Referring to FIG. 1 and FIG. 7, in a semiconductor device according to some embodiments, each of the first to seventh gate structures GS1 to GS7 further may include an inner spacer 136.

The inner spacer 136 may be formed, for example, within the second area II and may be formed on a side surface of the second gate electrode 230 and between the upper bridge patterns 211 and 212. The inner spacer 136 may be formed on a side surface of the second gate electrode 230 and between the intermediate insulating pattern 202 and the second active pattern 210. The second source/drain area 260 may be insulated from the second gate electrode 230 via the gate spacer 135, the inner spacer 136, and/or the gate dielectric film 120.

The inner spacer 136 is shown as not being formed within the first area I. However, this is only an example. Unlike what is shown, in some embodiments, the inner spacer 136 may be formed in both the first area I and the second area II. In some embodiments, unlike what is shown, the inner spacer 136 may be formed only in the first area I and not in the second area II.

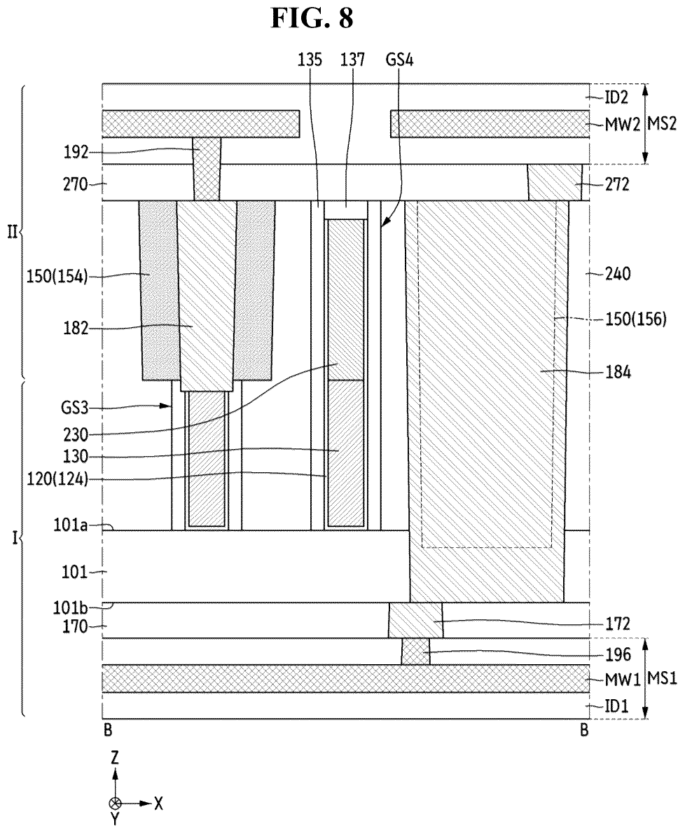

FIG. 8 is another cross-sectional view cut along B-B in FIG. 1, according to some embodiments. For convenience of description, components duplicated with those as described above using FIGS. 1 to 6 are briefly described or descriptions thereof are omitted for conciseness.

Referring to FIG. 1 and FIG. 8, in a semiconductor device according to some embodiments, the first via pattern 182 and/or the second via pattern 184 are electrically connected to the first wiring structure MS1.

For example, a rear via 196 may be formed so as to connect some of the first wiring patterns MW1 to the first connection contact 172. The second via pattern 184 may be connected to the first wiring structure MS1 via the first connection contact 172 and the rear via 196.

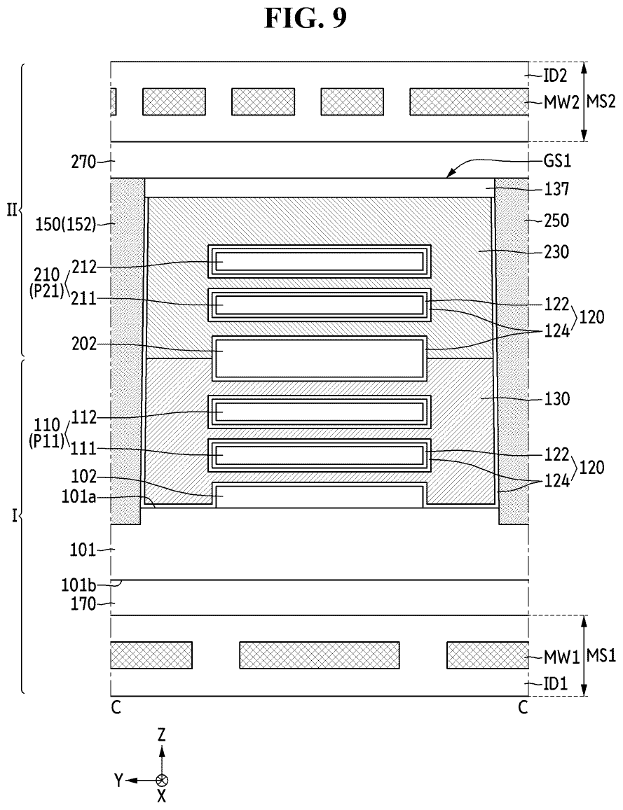

FIG. 9 is another cross-sectional view cut along C-C in FIG. 1, according to some embodiments. For convenience of description, components duplicated with those as described above using FIGS. 1 to 6 are briefly described or descriptions thereof are omitted for conciseness.

Referring to FIG. 1 and FIG. 9, in a semiconductor device according to some embodiments, the gate dielectric film 120 extends further along a side surface of the first cutting pattern 150 and a side surface of the second cutting pattern 250.

For example, the high-k dielectric layer 124 may extend conformally along a profile of the upper surface of the substrate 101, the side surface of the first cutting pattern 150, and the side surface of the second cutting pattern 250.

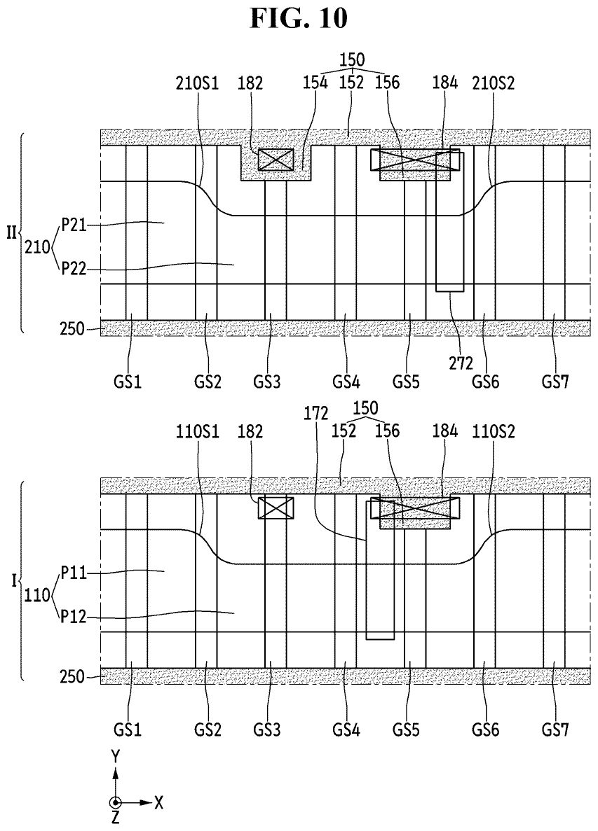

FIG. 10 is an example layout diagram for illustrating a semiconductor device according to some embodiments. For convenience of description, components duplicated with those as described above using FIGS. 1 to 9 are briefly described or descriptions thereof are omitted for conciseness.

Referring to FIG. 10, in a semiconductor device according to some embodiments, the side surface of the first active pattern 110 and/or the side surface of the second active pattern 210 may include a curved surface.

For example, a side surface of the first active pattern 110 facing the first cutting pattern 150 may include a first curved surface 110S1 and a second curved surface 110S2. The first curved surface 110S1 and the second curved surface 110S2 may be formed in a boundary area between the first portion P11 and the second portion P12. For example, the first curved surface 110S1 may intersect the second gate structure GS2, and the second curved surface 110S2 may intersect the sixth gate structure GS6.

In some embodiments, for example, a side surface of the second active pattern 210 facing the first cutting pattern 150 may include a third curved surface 210S1 and a fourth curved surface 210S2. The third curved surface 210S1 and the fourth curved surface 210S2 may be formed in a boundary area between the third portion P21 and the fourth portion P22. For example, the third curved surface 210S1 may intersect the second gate structure GS2, and the fourth curved surface 210S2 may intersect the sixth gate structure GS6.

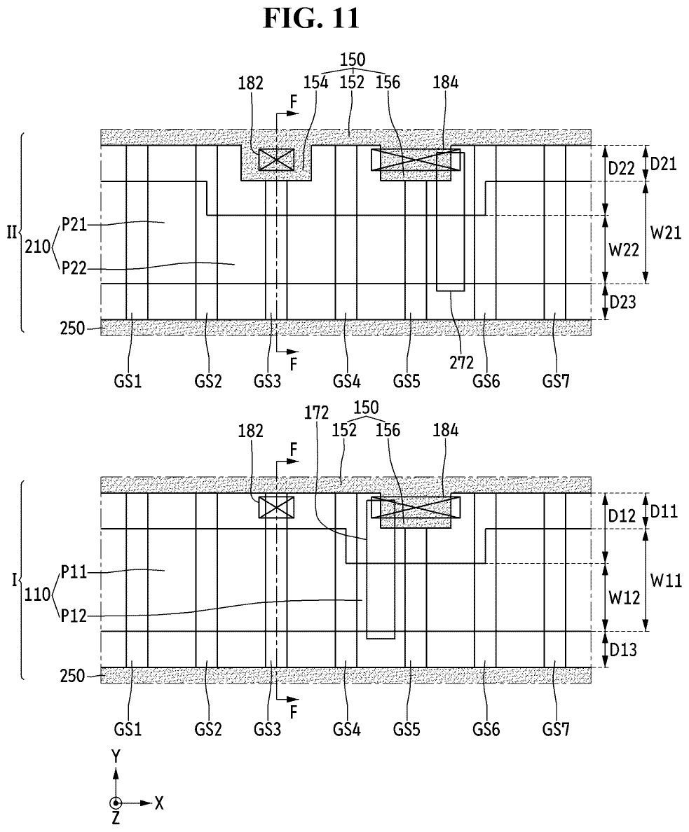

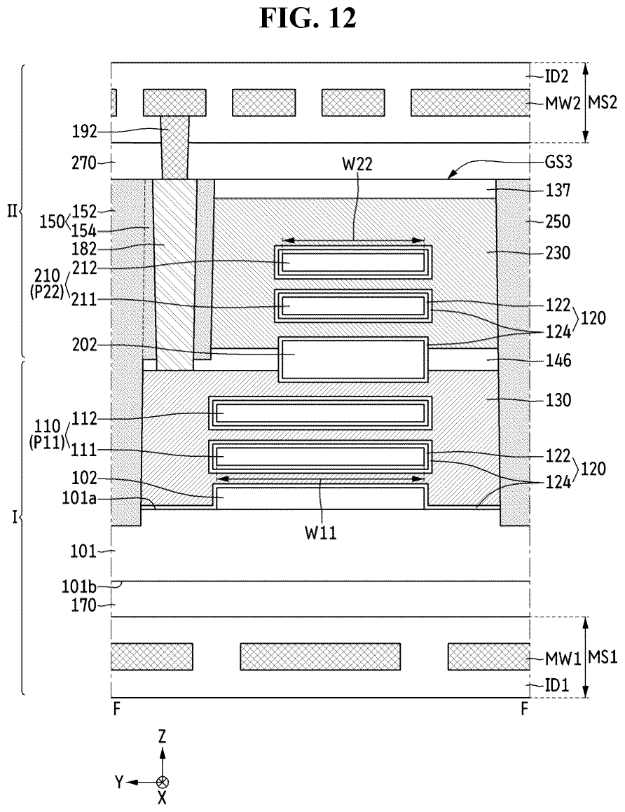

FIG. 11 is an example layout diagram for illustrating semiconductor devices according to some embodiments. FIG. 12 is a cross-sectional view cut along F-F in FIG. 11, according to some embodiments. For convenience of description, components duplicated with those as described above using FIGS. 1 to 10 are briefly described or descriptions thereof are omitted for conciseness.

Referring to FIG. 11 and FIG. 12, in a semiconductor device according to some embodiments, the third gate structure GS3 intersects the first portion P11 of the first active pattern 110.

In an area intersecting the third gate structure GS3, the first portion P11 of the first active pattern 110 and the fourth portion P22 of the second active pattern 210 may overlap each other in the vertical direction Z. The first protrusion 154 may not be interposed between the first line portion 152 and the first portion P11, but may be interposed between the first line portion 152 and the fourth portion P22. Accordingly, the first portion P11 may have a relatively larger width. For example, in an area intersecting the third gate structure GS3, the first width W11 of the first portion P11 may be larger than the fourth width W22 of the fourth portion P22. Thus, a semiconductor device with further improved integration density and performance may be provided.

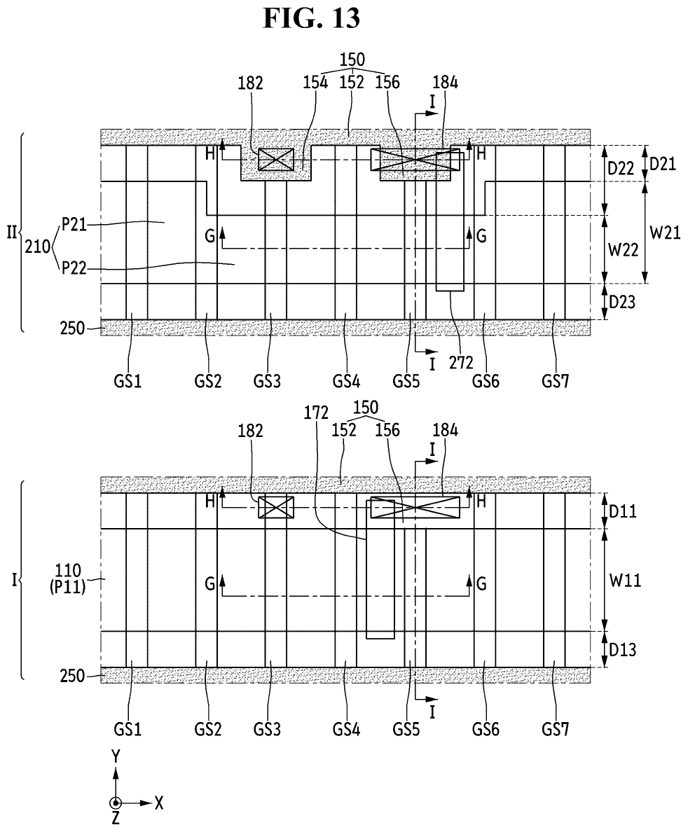

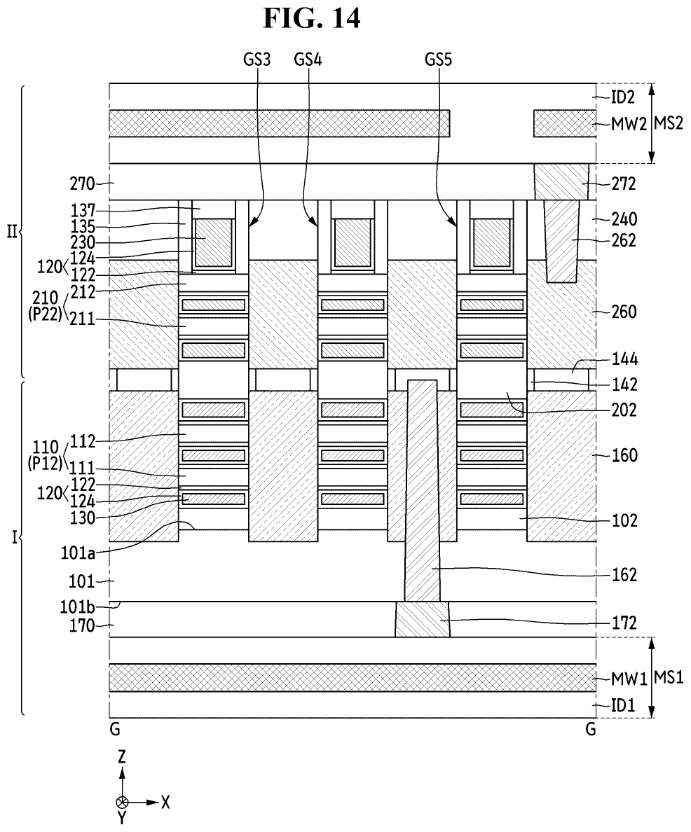

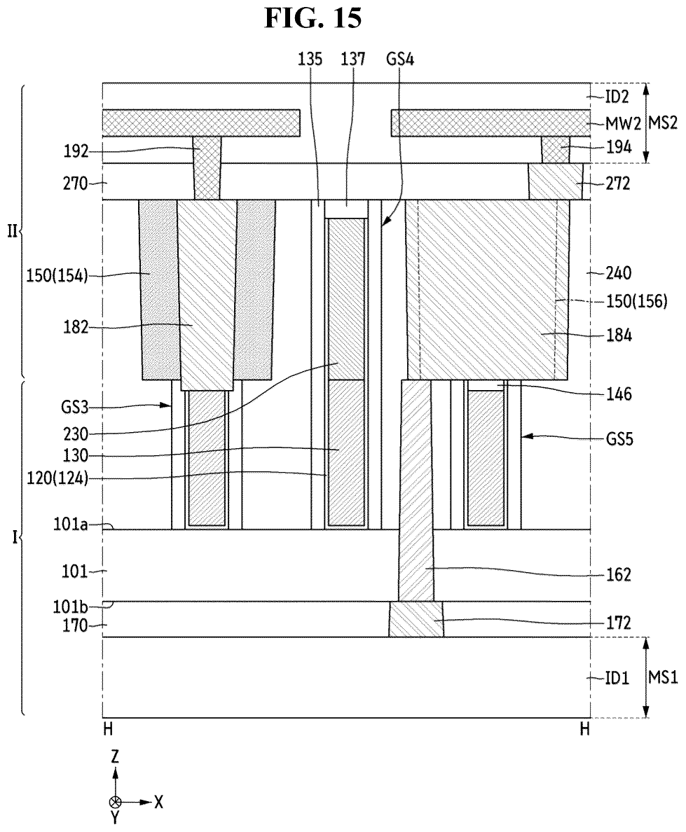

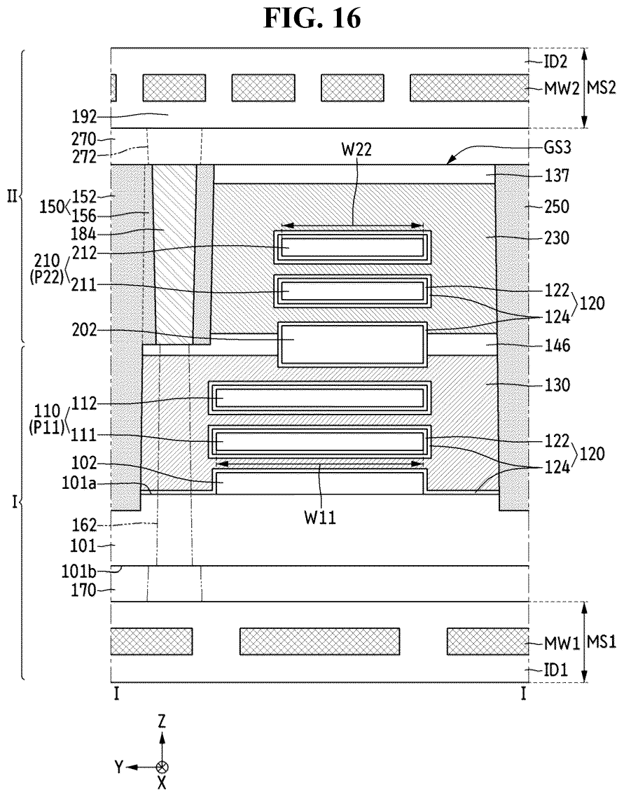

FIG. 13 is an example layout diagram for illustrating a semiconductor device according to some embodiments. FIG. 14 is a cross-sectional view cut along G-G in FIG. 13, according to some embodiments. FIG. 15 is a cross-sectional view cut along H-H in FIG. 13, according to some embodiments. FIG. 16 is a cross-sectional view cut along I-I in FIG. 13, according to some embodiments. For convenience of description, components duplicated with those as described above using FIGS. 1 to 10 are briefly described or descriptions thereof are omitted for conciseness.

Referring to FIGS. 13 to 16, in a semiconductor device according to some embodiments, the fifth gate structure GS5 intersects the first portion P11 of the first active pattern 110.

In an area intersecting the fifth gate structure GS5, the first portion P11 of the first active pattern 110 and the fourth portion P22 of the second active pattern 210 may overlap each other in the vertical direction Z. The second protrusion 156 may not be interposed between the first line portion 152 and the first portion P11, but may be interposed between the first line portion 152 and the fourth portion P22. Accordingly, the first portion P11 may have a relatively larger width. For example, in an area intersecting the fifth gate structure GS5, the first width W11 of the first portion P11 may be larger than the fourth width W22 of the fourth portion P22. Thus, a semiconductor device with further improved integration density and performance may be provided.

In some embodiments, the first source/drain contact 162 may extend through the first source/drain area 160. For example, a vertical level of the upper surface of the first source/drain contact 162 may be higher than a vertical level of the upper surface of the first source/drain area 160.

In some embodiments, the fifth gate structure GS5 may include a gate insulating pattern 146 between the first gate electrode 130 and the second gate electrode 230. The first gate electrode 130 and the second gate electrode 230 of the fifth gate structure GS5 may be insulated from each other via the gate insulating pattern 146. In FIG. 16, a vertical level of the lowermost surface of the second protrusion 156 is shown to be higher than a vertical level of the lowermost surface of the gate insulating pattern 146. However, this is only an example. As long as the second protrusion 156 cuts the second gate electrode 230, the vertical level of the lowermost surface of the second protrusion 156 may be equal to or lower than the vertical level of the lowermost surface of the gate insulating pattern 146.

The second via pattern 184 may extend through the second protrusion 156 so as to contact the first source/drain contact 162. For example, the first source/drain contact 162 may extend in the second direction Y so as to directly contact the second via pattern 184. In some embodiments, the second via pattern 184 may be insulated from the first gate electrode 130 via the gate insulating pattern 146. For example, the lower surface of the second via pattern 184 may be formed to a higher vertical level of than a vertical level of the lower surface of the gate insulating pattern 146.

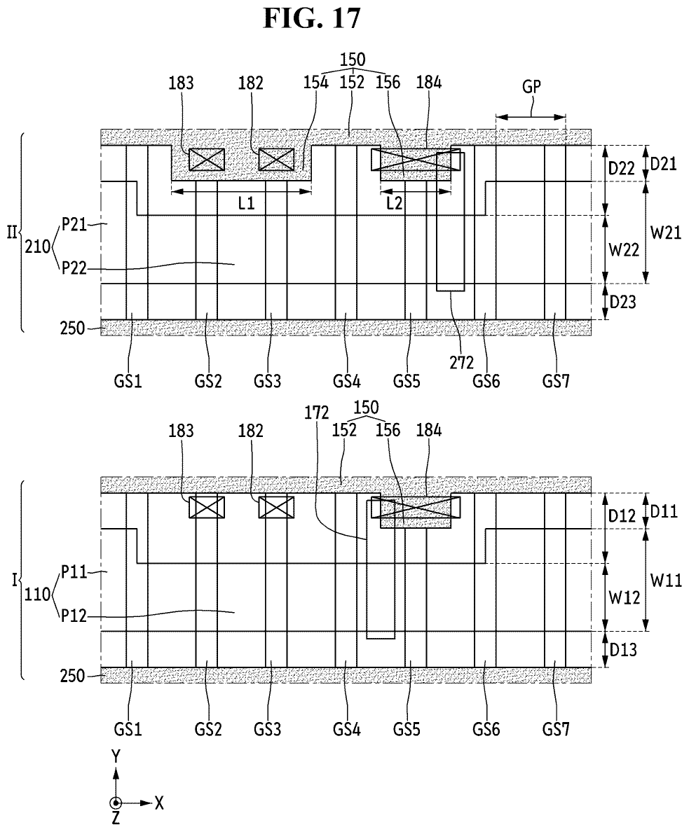

FIGS. 17 to 19 are various example layout diagrams for illustrating semiconductor devices according to some embodiments. For convenience of description, components duplicated with those as described above using FIGS. 1 to 10 are briefly described or descriptions thereof are omitted for conciseness.

Referring to FIG. 17, in a semiconductor device according to some embodiments, the first protrusion 154 may cut adjacent ones of the plurality of gate structures.

For example, the first protrusion 154 may be interposed between the second gate structure GS2 and the first line portion 152 and between the third gate structure GS3 and the first line portion 152. The first length L1 by which the first protrusion 154 extends in the first direction X may be equal or greater than about 2 gate pitches (2 GP).

In some embodiments, the first protrusion 154 may be interposed between the first gate structure GS1 and the fourth gate structure GS4. For example, the first length L1 by which the first protrusion 154 extends in the first direction X may be about 2 gate pitches (2 GP).

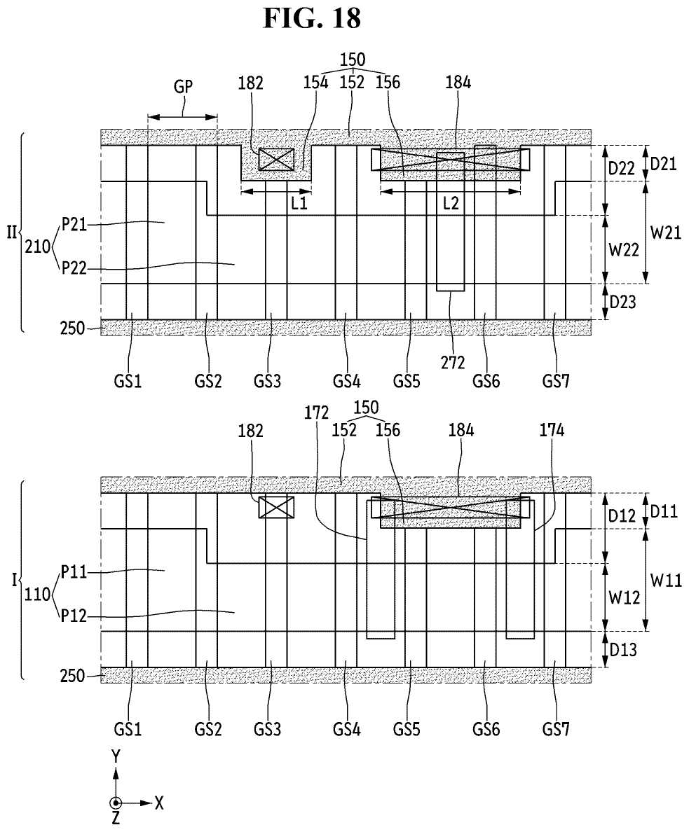

Referring to FIG. 18, in a semiconductor device according to some embodiments, the second protrusion 156 may cut adjacent ones of the plurality of gate structures.

For example, the second protrusion 156 may be interposed between the fifth gate structure GS5 and the first line portion 152 and between the sixth gate structure GS6 and the first line portion 152. The second length L2 by which the second protrusion 156 extends in the first direction X may be about 2 gate pitches (2 GP) or greater.

In some embodiments, the second protrusion 156 may be interposed between the fourth gate structure GS4 and the seventh gate structure GS7. For example, the second length L2 by which the second protrusion 156 extends in the first direction X may be about 2 gate pitches (2 GP).

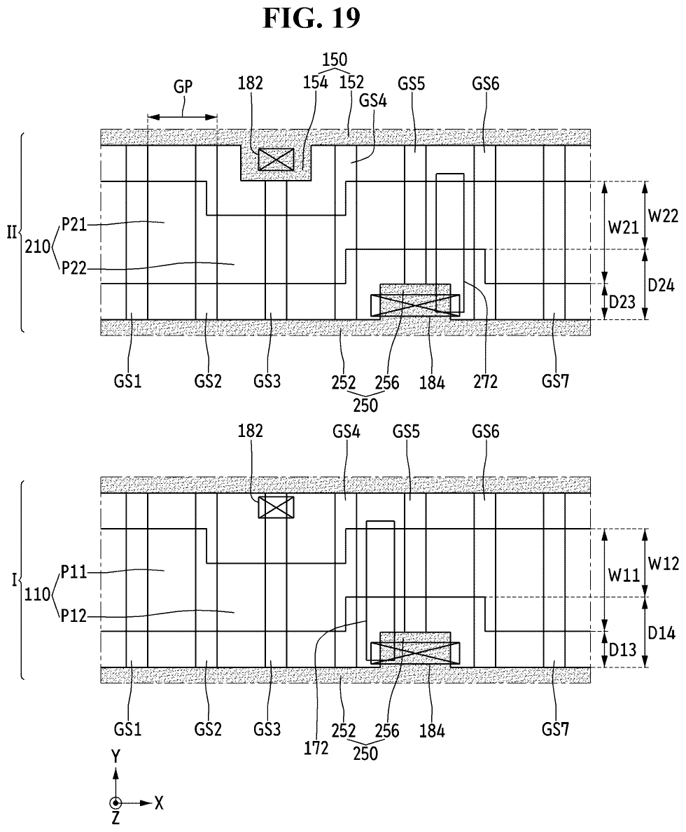

Referring to FIG. 19, in the semiconductor device according to some embodiments, the second cutting pattern 250 may include the second line portion 252 and a third protrusion 256.

The second line portion 252 extends in the first direction X to cut the first to seventh gate structures GS1 to GS7. The fifth distance D13 in the second direction Y between the first portion P11 of the first active pattern 110 and the second line portion 252 may be smaller than a seventh distance D14 in the second direction Y between the second portion P12 of the first active pattern 110 and the second line portion 252. The sixth distance D23 in the second direction Y between the third portion P21 of the second active pattern 210 and the second line portion 252 may be smaller than an eighth distance D24 in the second direction Y between the fourth portion P22 of the second active pattern 210 and the second line portion 252.

The third protrusion 256 may protrude from the second line portion 252 in the second direction Y. The third protrusion 256 may be interposed between the second line portion 252 and the fourth portion P22 of the second active pattern 210. A distance in the second direction Y between the third protrusion 256 and the fourth portion P22 is shown to be equal to the sixth distance D23. However, this is only an example. The third protrusion 256 may not overlap with the first protrusion 154 in the first direction X. In some embodiments, the third protrusion 256 may not overlap the first protrusion 154 in the second direction Y. For example, as shown, the first protrusion 154 and the third protrusion 256 may be arranged along a diagonal direction between the first direction X and the second direction Y.

The second via pattern 184 may extend in the vertical direction Z through the third protrusion 256. In some embodiments, the second via pattern 184 may contact at least one of the first active pattern 110 or the second active pattern 210. For example, the second via pattern 184 may contact at least one of the first connection contact 172 or the second connection contact 272.

Although the embodiments have been described above with reference to the accompanying drawings, the embodiments are not limited to those described and may be implemented in various different forms. Those of ordinary skill in the technical field to which the present disclosure belongs will be able to appreciate that embodiments may be implemented in other specific forms without changing the technical idea or essential features of the present disclosure. Therefore, it should be understood that the embodiments as described above are not restrictive but illustrative in all respects.

What is claimed is:

1. A semiconductor device comprising:
a first active pattern extending in a first direction;
a second active pattern extending in the first direction and being spaced apart from the first active pattern in a vertical direction intersecting the first direction;
a first gate structure on the first active pattern and the second active pattern, the first gate structure extending in a second direction intersecting the first direction and the vertical direction;
a first cutting pattern spaced apart from the first active pattern and the second active pattern in the second direction, the first cutting pattern extending in the first direction and cutting the first gate structure; and
a via pattern spaced apart from the second active pattern in the second direction,
wherein the second active pattern includes:
a first portion having a first width in the second direction; and
a second portion having a second width in the second direction that is smaller than the first width,
wherein the first cutting pattern includes:
a first line portion extending in the first direction; and
a first protrusion between the first line portion and the second portion, the first protrusion protruding from the first line portion in the second direction, and
wherein the via pattern extends in the vertical direction and extends through the first protrusion.

2. The semiconductor device of claim 1, wherein the first protrusion is interposed between the first line portion and the first gate structure.

3. The semiconductor device of claim 2, wherein the first gate structure includes a first gate electrode intersecting the first active pattern, and a second gate electrode intersecting the second active pattern,
wherein the first protrusion is omitted between the first line portion and the first gate electrode, and is interposed between the first line portion and the second gate electrode.

4. The semiconductor device of claim 3, wherein the via pattern is connected to the first gate electrode.

5. The semiconductor device of claim 3, wherein the first active pattern includes a third portion having a third width in the second direction that is greater than the second width,
wherein the second portion overlaps the third portion in the vertical direction.

6. The semiconductor device of claim 1, wherein the first active pattern includes:
a third portion having a third width in the second direction; and
a fourth portion having a fourth width in the second direction that is smaller than the third width,
wherein the first protrusion is interposed between the first line portion and the fourth portion.

7. The semiconductor device of claim 6, further comprising a source/drain contact on a side surface of the first gate structure,
wherein the source/drain contact is connected to at least one of a first source/drain area of the first active pattern or a second source/drain area of the second active pattern, and
wherein the via pattern is connected to the source/drain contact.

8. The semiconductor device of claim 6, wherein the first protrusion is interposed between the first line portion and the first gate structure.

9. The semiconductor device of claim 1, wherein the first cutting pattern further includes a second protrusion spaced apart from the first protrusion in the first direction, the second protrusion protruding from the first line portion in the second direction.

10. The semiconductor device of claim 1, further comprising a second gate structure on the first active pattern and the second active pattern, the second gate structure being spaced apart from the first gate structure in the first direction and extending in the second direction,
wherein the first protrusion is interposed between the first line portion and the first gate structure and between the first line portion and the second gate structure.

11. The semiconductor device of claim 1, further comprising a second cutting pattern spaced apart from the first active pattern and the second active pattern in the second direction, the second cutting pattern extending in the first direction and cutting the first gate structure,
wherein the first active pattern and the second active pattern are interposed between the first cutting pattern and the second cutting pattern.

12. The semiconductor device of claim 11, wherein the second cutting pattern includes:
a second line portion extending in the first direction; and
a second protrusion between the second line portion and the second portion, the second protrusion protruding from the second line portion in the second direction.

13. A semiconductor device comprising:
a substrate including a first surface and a second surface opposite to the first surface;
a first active pattern and a second active pattern sequentially stacked on the first surface along a vertical direction that intersects the first surface, the first active pattern and the second active pattern extending in a first direction and being spaced apart from each other;
a gate structure extending in a second direction intersecting the first direction and the vertical direction, the gate structure including a first gate electrode intersecting the first active pattern and a second gate electrode intersecting the second active pattern;
a cutting pattern spaced apart from the first active pattern and the second active pattern in the second direction, the cutting pattern extending in the first direction and cutting the gate structure; and
a via pattern spaced apart from the second active pattern in the second direction,
wherein the second active pattern includes:
a first portion having a first width in the second direction; and
a second portion having a second width in the second direction that is smaller than the first width,
wherein the cutting pattern includes:
a line portion extending in the first direction; and
a protrusion between the line portion and the second gate electrode, the protrusion protruding from the line portion in the second direction, and
wherein the via pattern extends in the vertical direction to extend through the protrusion, and is connected to the first gate electrode.

14. The semiconductor device of claim 13, wherein the first active pattern includes a third portion having a third width in the second direction that is greater than the second width,
wherein the second portion overlaps the third portion in the vertical direction.

15. The semiconductor device of claim 13, further comprising a gate insulating pattern between the first gate electrode and the second gate electrode, the gate insulating pattern extending in the second direction,
wherein the via pattern extends through the gate insulating pattern.

16. The semiconductor device of claim 13, further comprising a wiring structure electrically connected to the via pattern, on the second surface.

17. A semiconductor device comprising:
a substrate including a first surface and a second surface opposite to the first surface;
a first active pattern and a second active pattern sequentially stacked on the first surface along a vertical direction that intersects the first surface, the first active pattern and the second active pattern extending in a first direction and being spaced apart from each other;
a gate structure on the first active pattern and the second active pattern, the gate structure extending in a second direction intersecting the first direction and the vertical direction;
a first source/drain contact on a side surface of the gate structure, the first source/drain contact being connected to a first source/drain area of the first active pattern;
a second source/drain contact on a side surface of the gate structure, the second source/drain contact being connected to a second source/drain area of the second active pattern;
a cutting pattern spaced apart from the first active pattern and the second active pattern in the second direction, the cutting pattern extending in the first direction and cutting the gate structure; and
a via pattern spaced apart from the first active pattern and the second active pattern in the second direction,
wherein the second active pattern includes:
a first portion having a first width in the second direction; and
a second portion having a second width in the second direction that is smaller than the first width,
wherein the cutting pattern includes:
a line portion extending in the first direction; and
a protrusion between the line portion and the second portion, the protrusion protruding from the line portion in the second direction, and
wherein the via pattern extends in the vertical direction to extend through the protrusion, and is connected to at least one of the first source/drain contact or the second source/drain contact.

18. The semiconductor device of claim 17, wherein the first active pattern includes:
a third portion having a third width in the second direction: and
a fourth portion having a fourth width in the second direction that is smaller than the third width,
wherein the protrusion is interposed between the line portion and the fourth portion.

19. The semiconductor device of claim 17, wherein the via pattern connects the first source/drain contact to the second source/drain contact.

20. The semiconductor device of claim 17, further comprising a wiring structure electrically connected to the via pattern, on the second surface.
